(19) United States
(12) Patent Application Publication
(10) Pub. No.: US 2012/0060923 A1
(43) Pub. Date: Mar. 15, 2012

(54) PHOTOVOLTAIC DEVICE BARRIER LAYER

(76) Inventors: Zhibo Zhao, Novi, MI (US); Yu Yang, Perrysburg, OH (US); Benyamin Buller, Perrysburg, OH (US); Keith J. Burrows, Mineral Point, WI (US); Annette Krisko, Spring Green, WI (US)

(21) Appl. No.: 13/075,998

(22) Filed: Mar. 30, 2011

Related U.S. Application Data
(60) Provisional application No. 61/319,683, filed on Mar. 31, 2010.

(51) Int. Cl. H01L 31/0264; H01L 31/18

(52) U.S. Cl. 136/260; 136/252; 438/98; 257/E31.126

(57) ABSTRACT

A structure including a barrier layer adjacent to a substrate, a transparent conductive oxide layer adjacent to the barrier layer, and a buffer layer adjacent to the transparent conductive oxide layer. In the structure, the barrier layer includes a silicon aluminum oxide, the transparent conductive oxide layer includes cadmium and tin and the buffer layer comprises tin oxide. A photovoltaic device that includes the described structure along with a semiconductor window layer adjacent to the buffer layer and a semiconductor absorber layer adjacent to the semiconductor window layer. Methods of manufacturing a photovoltaic structure are also disclosed, as well as a sputter target for use in the manufacture of a photovoltaic device and methods of manufacturing the same.

### CLAIM FOR PRIORITY

This application claims priority under 35 U.S.C. §119(e) to U.S. Provisional Patent Application Ser. No. 61/319,683 filed on Mar. 31, 2010, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices have not been highly efficient.

### DESCRIPTION OF DRAWINGS

FIG. 1 is a schematic of a multilayered substrate.

FIG. 2 is a schematic of a photovoltaic device having multiple layers.

### DETAILED DESCRIPTION

Photovoltaic devices can include multiple layers formed on a substrate (or superstrate). For example, a photovoltaic device can include a barrier layer, a transparent conductive oxide (TCO) layer, a buffer layer, a semiconductor window layer adjacent to the buffer layer, and a semiconductor absorber layer adjacent to the semiconductor window layer formed in a stack on a substrate. Each layer may in turn include more than one layer or film. For example, the semiconductor layer can include a first film including a semiconductor window layer formed on the buffer layer and a second film including a semiconductor absorber layer formed on the semiconductor window layer. Additionally, each layer can cover all or a portion of the device and/or all or a portion of the layer or substrate underlying the layer. For example, a “layer” can mean any amount of any material that contacts all or a portion of a surface.

In one aspect, a structure can include a barrier layer adjacent to a substrate. The barrier layer can include a silicon aluminum oxide. The structure can include a transparent conductive oxide layer adjacent to the barrier layer. The transparent conductive oxide layer can include cadmium and tin. The structure can include a tin oxide buffer layer adjacent to the transparent conductive oxide layer. The substrate can include a glass. The glass can be capable of transmitting more than about 50% of light having a wavelength in the range of 400 nm to 850 nm. The glass can be capable of transmitting more than about 70% of light having a wavelength in the range of 400 nm to 850 nm. The glass can be capable of transmitting more than about 85% of light having a wavelength in the range of 400 nm to 850 nm. The glass can include a substantially round edge.

The structure can include a second buffer layer between the transparent conductive oxide layer and the tin oxide buffer layer, wherein the second buffer layer comprises an oxide. The barrier layer can have a thickness of about 500 A to about 1500 A. The barrier layer can have a thickness of about 1000 A. The transparent conductive oxide layer can have a thickness of about 1000 A to about 4000 A. The transparent conductive oxide layer can have a thickness of about 2000 A to about 3000 A. The transparent conductive oxide layer can have a thickness of about 2600 A. The buffer layer can have a thickness of about 200 A to about 1500 A. The buffer layer can have a thickness of less than about 900 A. The layer of cadmium and tin can include a cadmium tin oxide. The layer of cadmium and tin can include a cadmium stannate. The structure can include a cadmium sulfide layer on the tin oxide, and a cadmium telluride layer on the cadmium sulfide layer.

In one aspect, a photovoltaic device can include a barrier layer adjacent to a substrate, a transparent conductive oxide layer adjacent to the barrier layer, a buffer layer adjacent to the transparent conductive oxide layer, a semiconductor window layer adjacent to the buffer layer, and a semiconductor absorber layer adjacent to the semiconductor window layer. The barrier layer can include silicon aluminum oxide. The transparent conductive oxide can include cadmium stannate. The buffer layer can include tin oxide. The semiconductor window layer can include cadmium sulfide. The semiconductor absorber layer can include cadmium telluride.

The substrate can include a glass. The glass can include a reduced iron content. The glass can have a transmittance of about 400 nm to about 850 nm. The glass can have a transmittance percentage of more than about 50%. The glass can have a transmittance percentage of more than about 75%. The glass can have a transmittance percentage of more than about 85%. The one or more edges of the glass can be substantially rounded.

In one aspect, a method of manufacturing a photovoltaic structure can include forming a barrier layer on a substrate, forming a transparent conductive oxide layer adjacent to the barrier layer, forming a buffer layer adjacent to the transparent conductive oxide layer, and annealing the substrate to form an annealed transparent conductive oxide stack adjacent to the substrate. The barrier layer can include silicon aluminum oxide. The transparent conductive oxide layer can include cadmium stannate. The buffer layer can include tin oxide.

The method can include forming a semiconductor window layer adjacent to the annealed transparent conductive oxide stack. The method can include forming a semiconductor absorber layer adjacent to the semiconductor window layer. The step of forming the barrier layer can include sputtering in an environment comprising argon and oxygen. The step of forming the transparent conductive oxide layer can include sputtering in an environment comprising argon and oxygen. The step of forming the buffer layer can include sputtering in an environment comprising argon and/or oxygen.

The method can include rounding one or more edges of the substrate, wherein the substrate can include the glass. The annealing can include heating the stack above about 400 degrees C. The annealing can include heating the stack above about 500 degrees C. The annealing can include heating the stack below about 600 degrees C.

In one aspect, a sputter target can include a sputter material including silicon and aluminum and a backing tube. The sputter material can be connected to the backing tube to form a sputter target. The sputter material can include 5-35 wt. % aluminum. The sputter material can include 15-20 wt. % aluminum. The sputter target can include a bonding layer bonding the sputter material and the backing tube. The backing tube can include stainless steel. The sputter target can be configured to use in reactive sputtering process.

In one aspect, a method of manufacturing a rotary sputter target configured for use in manufacture of photovoltaic device can include forming a sputter material including silicon and aluminum and attaching the sputter material to a backing tube to form a sputter target. The step of attaching the sputter material to a backing tube to form a sputter target can include a thermal spray forming process. The step of attaching the sputter material to a backing tube to form a sputter target can include a plasma spray forming process. The step of attaching the sputter material to a backing tube to form a sputter target can include a powder metallurgy process. The powder metallurgy can include hot press process. The powder metallurgy can include an isostatic process. The step of attaching the sputter material to a backing tube to form a sputter target can include a flow forming process. The step of attaching the sputter material to the backing tube can include bonding the sputtering material to the backing tube with a bonding layer.

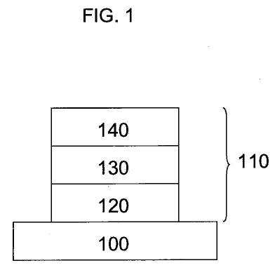

Referring to FIG. 1, by way of example, barrier layer 120 may be deposited onto substrate 100. Substrate 100 may include any suitable material, including, for example, a glass. The glass may include a soda-lime glass, or any glass with reduced iron content. The glass may undergo a treatment step, during which one or more edges of the glass may be substantially rounded. The glass may have any suitable transmittance, including about 400 nm to about 850 nm. The glass may also have any suitable transmission percentage, including, for example, more than about 50%, more than about 60%, more than about 70%, more than about 80%, or more than about 85%. For example, substrate 100 may include a glass with about 90% transmittance.

Barrier layer 120 may include any suitable material, including, for example, a silicon aluminum oxide. Barrier layer 120 can be incorporated between the substrate and the TCO layer to lessen diffusion of sodium or other contaminants from the substrate to the semiconductor layers, which could result in degradation or delamination. Barrier layer 120 can be transparent, thermally stable, with a reduced number of pin holes and having high sodium-blocking capability, and good adhesive properties. Barrier layer 120 can include any suitable number of layers and may have any suitable thickness, including, for example, more than about 500 A, more than about 750 A, less than about 3000 A, or less than about 1200 A. For example, barrier layer 120 may have a thickness of about 1000 A. Barrier layer 120 may be deposited using any suitable technique, including, for example, sputtering. Barrier layer 120 may be deposited in the presence of one or more gases, for example, an oxygen gas. An argon gas may be added to the deposition chamber to increase the rate of deposition. For example, barrier layer 120 may include a silicon aluminum oxide sputtered in the presence of an oxygen/argon gas mix. The incorporation of argon into the deposition process can result in a higher deposition rate for barrier layer 120.

A transparent conductive oxide layer 130 can be formed adjacent to barrier layer 120. Transparent conductive oxide layer 130 may include any suitable material, including, for example, a layer of cadmium stannate. Transparent conductive oxide layer 130 may have any suitable thickness, including more than about 2000 A, more than about 2500 A, or less than about 3000 A. For example, transparent conductive oxide layer 130 may have a thickness of about 2600 A. Transparent conductive oxide layer 130 may be deposited using any suitable means, including, for example, sputtering. Like barrier layer 120, transparent conductive oxide layer 130 may be deposited at an enhanced rate by incorporating argon gas into the deposition environment. For example, transparent conductive oxide layer 130 may be deposited in the presence of an oxygen/argon gas mix. An argon content in barrier layer 120 and transparent conductive oxide layer 130 may be detectable following deposition. For example, barrier layer 120 or transparent conductive oxide layer 130 can either or both include argon in an amount of 1-10,000 ppm, for example, 10-1,000 ppm.

A buffer layer 140 may be formed onto transparent conductive oxide layer 130. Buffer layer 140 can be deposited between the TCO layer and a semiconductor window layer to decrease the likelihood of irregularities occurring during the formation of the semiconductor window layer. Buffer layer 140 may include any suitable material, including, for example, an amorphous tin oxide. Buffer layer 140 can include any other suitable material, including zinc tin oxide, zinc oxide, and zinc magnesium oxide. Buffer layer 140 may have any suitable thickness, including, for example, more than about 500 A, more than about 650 A, more than about 800 A, or less than about 1200 A. For example, buffer layer 140 may have a thickness of about 900 A. Buffer layer 140 may be deposited using any suitable means, including, for example, sputtering. For example, buffer layer 140 may include a tin oxide sputtered in the presence of an oxygen gas. Buffer layer 140, along with barrier layer 120 and transparent conductive oxide layer 130, can form transparent conductive oxide stack 110.

The layers included in the structure and photovoltaic device can be created using any suitable technique or combination of techniques. For example, the layer can be formed by low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of about 1 to about 5000 A.

The deposition rate of the TCO stack may be expedited by incorporating an argon gas into the deposition chamber, in addition to oxygen gas. For example, the barrier and/or TCO layer can be sputtered in the presence of an oxygen/argon gas mix to facilitate the deposition process. A silicon aluminum oxide can be deposited onto a glass substrate, which may include any suitable glass, including, for example, soda-lime glass or any glass with a reduced iron content. The glass may have one or more rounded edges to enable the substrate to withstand high anneal temperatures (e.g., about 600 degrees C.). The TCO layer may have a low roughness to facilitate smooth cadmium sulfide deposition, thereby resulting in greater control of the cadmium sulfide/cadmium telluride junction interface. The TCO layer, which may include a cadmium tin oxide, for example, may be deposited on the silicon aluminum oxide, in the presence of an oxygen/argon gas mix. The incorporation of argon during the sputtering of the silicon aluminum oxide and the cadmium tin oxide can increase the deposition rate by a factor of about 2.

The barrier layer, transparent conductive oxide layer, and/or buffer layer can be formed by sputtering respective sputter targets including suitable sputter materials. For example, if the barrier layer includes silicon aluminum oxide (e.g., SiAlOₓ), the sputter target can include suitable amounts of silicon and aluminum. The sputter target can be sputtered in an oxygen-containing environment. For example, the target can have a silicon:aluminum ratio in the range of 95:5 to 65:35. The target can have a silicon:aluminum ratio in the range of 80:20 to 85:15. A sputter target for creating a cadmium stannate transparent conductive oxide layer can include cadmium and tin. A sputter target for forming a tin oxide buffer layer can include tin and can be sputtered in an oxygen-containing environment.

A sputter target can be manufactured by ingot metallurgy. A sputter target can be manufactured as a single piece in any suitable shape. A sputter target can be a tube. A sputter target can be manufactured by casting a material into any suitable shape, such as a tube.

A sputter target can be manufactured from more than one piece. For example, if a sputter target includes a cadmium and tin sputter material, the target can be manufactured from more than one piece, such as a piece of cadmium and a piece of tin. The pieces can be manufactured in any suitable shape, such as sleeves, and can be joined or connected in any suitable manner or configuration. For example, a piece of cadmium and a piece of tin can be welded together to form the sputter target. One sleeve can be positioned within another sleeve. A sputter target for a silicon aluminum oxide barrier layer can include a piece of silicon and a piece of aluminum.

A sputter target can be manufactured by powder metallurgy. A sputter target can be formed by consolidating powder (e.g., silicon and aluminum for the barrier target or cadmium and tin for the TCO target) to form the target. The powder can be consolidated in any suitable process (e.g., pressing such as isostatic pressing) and in any suitable shape. The consolidating can occur at any suitable temperature. A sputter target can be formed from powder including more than one material powder (e.g., silicon and aluminum or cadmium and tin). More than one powder can be present in stoichiometrically proper amounts.

Sputter targets (including rotary sputter targets) can include a sputter material used in connection with a backing material. The backing material can include stainless steel. The backing material can include a backing tube. The backing material can include a stainless steel backing tube. The sputter target for a silicon aluminum oxide barrier layer can include bonding layers applied to the tube surface before application of the silicon:aluminum sputter material.

A sputter target can be manufactured by positioning wire including target material adjacent to a base. For example wire including target material can be wrapped around a base tube. The wire can include multiple materials (e.g., cadmium and tin for a cadmium stannate TCO layer) present in stoichiometrically proper amounts. The base tube can be formed from a material that will not be sputtered. The wire can be pressed (e.g., by isostatic pressing).

A sputter target can be manufactured by spraying a sputter material onto a base. Sputter material can be sprayed by any suitable spraying process, including thermal spraying and plasma spraying. The sputter material can include multiple materials (e.g., silicon and aluminum for a silicon aluminum oxide barrier layer), present in stoichiometrically proper amounts. The base onto which the target material is sprayed can be a tube.

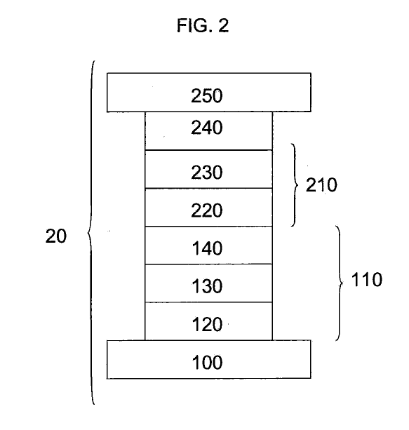

Following deposition, transparent conductive oxide stack 110 can be annealed to form annealed stack 210 from FIG. 2, which can lead to formation of cadmium stannate. Transparent conductive oxide stack 110 can be annealed using any suitable annealing process. The annealing can occur in the presence of a gas selected to control an aspect of the annealing, for example, nitrogen gas. Transparent conductive oxide stack 110 can be annealed under any suitable pressure, for example, under reduced pressure, in a low vacuum, or at about 0.01 Pa (10⁻⁴ Torr). Transparent conductive oxide stack 110 can be annealed at any suitable temperature or temperature range. For example, transparent conductive oxide stack 110 can be annealed above about 380 degrees C., above about 400 degrees C., above about 500 degrees C., above about 600 degrees C., or below about 800 degrees C. For example, transparent conductive oxide stack 110 can be annealed at about 400 degrees C. to about 800 degrees C. or about 500 degrees C. to about 700 degrees C. Transparent conductive oxide stack 110 can be annealed for any suitable duration. Transparent conductive oxide stack 110 can be annealed for more than about 10 minutes, more than about 20 minutes, more than about 30 minutes, or less than about 40 minutes. For example, transparent conductive oxide stack 110 can be annealed for about 15 to about 20 minutes.

Annealed transparent conductive oxide stack 110 can be used to form photovoltaic device 20 from FIG. 2. Referring to FIG. 2, a semiconductor stack 210 can be deposited onto annealed transparent conductive oxide stack 110. Semiconductor stack 210 can include a semiconductor window layer 220 and a semiconductor absorber layer 230. Semiconductor window layer 220 can be deposited directly onto annealed transparent conductive oxide stack 110. Semiconductor window layer 220 can be deposited using any known deposition technique, including vapor transport deposition. Semiconductor absorber layer 230 can be deposited onto semiconductor window layer 220. Semiconductor absorber layer 230 can be deposited using any known deposition technique, including vapor transport deposition. Semiconductor window layer 220 can include a cadmium sulfide layer. Semiconductor absorber layer 230 can include a cadmium telluride layer. A back contact 240 can be deposited onto semiconductor stack 210. Back contact 240 can be deposited onto semiconductor absorber layer 230. A back support 250 can be deposited onto back contact 240.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

1. A structure, comprising:
a barrier layer adjacent to a substrate, wherein the barrier layer comprises a silicon aluminum oxide;
a transparent conductive oxide layer adjacent to the barrier layer, wherein the transparent conductive oxide layer comprises cadmium and tin; and
a buffer layer adjacent to the transparent conductive oxide layer, wherein the buffer layer comprises tin oxide.

2. The structure of claim 1, wherein the substrate comprises a glass.

3. The structure of claim 2, wherein the glass is capable of transmitting more than about 50% of light having a wavelength in the range of 400 nm to 850 nm.

4. The structure of claim 3, wherein the glass is capable of transmitting more than about 70% of light having a wavelength in the range of 400 nm to 850 nm.

5. The structure of claim 3, wherein the glass is capable of transmitting more than about 85% of light having a wavelength in the range of 400 nm to 850 nm.

6. The structure of claim 1, wherein the glass comprises a substantially round edge.

7. The structure of claim 1, further comprising a second buffer layer between the transparent conductive oxide layer and the tin oxide buffer layer, wherein the second buffer layer comprises an oxide.

8. The structure of claim 1, wherein the barrier layer has a thickness of about 500 A to about 1500 A.

9. The structure of claim 1, wherein the barrier layer has a thickness of about 1000 A.

10. The structure of claim 1, wherein the transparent conductive oxide layer has a thickness of about 1000 A to about 4000 A.

11. The structure of claim 10, wherein the transparent conductive oxide layer has a thickness of about 2000 A to about 3000 A.

12. The structure of claim 11, wherein the transparent conductive oxide layer has a thickness of about 2600 A.

13. The structure of claim 1, wherein the buffer layer has a thickness of about 200 A to about 1500 A.

14. The structure of claim 13, wherein the buffer layer has a thickness of less than about 900 A.

15. The structure of claim 1, wherein the transparent conductive oxide layer comprises cadmium stannate.

16. The structure of claim 1, wherein the barrier layer, the transparent conductive oxide layer, and the buffer layer are annealed.

17. The structure of claim 16, further comprising cadmium sulfide-containing semiconductor window layer adjacent to the buffer layer a cadmium telluride-containing semiconductor absorber layer adjacent to the semiconductor window layer.

18. A photovoltaic device, comprising:
a barrier layer adjacent to a substrate, wherein the barrier layer comprises silicon aluminum oxide;
a transparent conductive oxide layer adjacent to the barrier layer, wherein the transparent conductive oxide comprises cadmium stannate;
a buffer layer adjacent to the transparent conductive oxide layer, wherein the buffer layer comprises tin oxide;
a semiconductor window layer adjacent to the buffer layer and comprising cadmium sulfide; and
a semiconductor absorber layer adjacent to the semiconductor window layer and comprising cadmium telluride.

19. The photovoltaic device of claim 18, wherein the substrate comprises a glass.

20. The photovoltaic device of claim 19, wherein the glass comprises a reduced iron content.

21. The photovoltaic device of claim 19, wherein the glass has a transmittance of about 400 nm to about 850 nm.

22. The photovoltaic device of claim 19, wherein the transparent conductive oxide layer is annealed.

23. The photovoltaic device of claim 22, wherein the glass has a transmittance percentage of more than about 75%.

24. The photovoltaic device of claim 23, wherein the glass has a transmittance percentage of more than about 85%.

25. The photovoltaic device of claim 19, wherein one or more edges of the glass is substantially round.

26. A method of manufacturing a photovoltaic structure comprising:
forming a barrier layer on a substrate, wherein the barrier layer comprises silicon aluminum oxide;
forming a transparent conductive oxide layer adjacent to the barrier layer, wherein the transparent conductive oxide layer comprises cadmium stannate;
forming buffer layer adjacent to the transparent conductive oxide layer, wherein the buffer layer comprises tin oxide; and
annealing the substrate to form an annealed transparent conductive oxide stack adjacent to the substrate.

27. The method of claim 26, further comprising forming a semiconductor window layer adjacent to the annealed transparent conductive oxide stack.

28. The method of claim 27, further comprising forming a semiconductor absorber layer adjacent to the semiconductor window layer.

29. The method of claim 26, wherein the step of forming the barrier layer comprises sputtering in an environment comprising argon and oxygen.

30. The method of claim 26, wherein the step of forming the transparent conductive oxide layer comprises sputtering in an environment comprising argon and oxygen.

31. The method of claim 26, wherein the step of forming the buffer layer comprises sputtering in an environment comprising oxygen.

32. The method of claim 26, further comprising rounding one or more edges of a glass, wherein the substrate comprises the glass.

33. The method of claim 26, wherein the annealing comprises heating the stack above about 400 degrees C.

34. The method of claim 26, wherein the annealing comprises heating the stack above about 500 degrees C.

35. The method of claim 26, wherein the annealing comprises heating the stack below about 600 degrees C.

36-49. (canceled)
